(19) United States
(12) Patent Application Publication
(10) Pub. No.: US 2011/0311717 A1
(43) Pub. Date: Dec. 22, 2011

(54) VAPOR DEPOSITION METHOD AND VAPOR DEPOSITION SYSTEM

(76) Inventors: Yasuo YAMAZAKI, Otsu-shi (JP); Hiroshi Takimoto, Otsu-shi (JP); Tatsuya Takaya, Otsu-shi (JP)

(21) Appl. No.: 13/151,435

(22) Filed: Jun. 2, 2011

(30) Foreign Application Priority Data
Jun. 16, 2010 (JP) 2010-137577

(51) Int. Cl. C23C 16/44; B05D 5/06; B05D 5/12

(52) U.S. Cl. 427/66; 427/248.1; 118/724

(57) ABSTRACT

Provided is a vapor deposition method of forming one or a plurality of layers on a one surface (7a) side of a glass substrate (7), the one or the plurality of layers including an organic layer (4), the vapor deposition method including: forming at least one layer of the one or the plurality of layers by vapor deposition treatment; and in the vapor deposition treatment, bringing one surface (15a) of a cooling plate (15) for cooling the glass substrate (7) into direct surface contact with another surface (7b) of the glass substrate (7), and bringing the contact surfaces (7b and 15a) of the cooling plate and the glass substrate into an intimate contact with each other to an extent of being peelable by the direct surface contact.

### TECHNICAL FIELD

The present invention relates to a vapor deposition method and a vapor deposition system, and more particularly, to a vapor deposition technology for forming an organic layer on a glass substrate.

### BACKGROUND ART

As is well known, in recent years, flat panel displays (hereinafter, simply referred to as FPD) represented by a liquid crystal display (LCD), a plasma display (PDP), a field emission display (FED), an organic electroluminescence (hereinafter, also simply referred to as organic EL) display, and the like have gone mainstream as image display devices. With regard to such FPDs, while the screen is becoming larger and larger, improvements toward lighter weight have been achieved. As a result, demand for thinner FPDs still remains strong. In particular, an organic EL display is required to be easily portable by being folded or by being wound up, and at the same time, required to be usable not only when the organic EL display is in a plate-like state but also when the organic EL display is in a curved state, and thus thinning of an organic EL panel which forms the display has become indispensable.

Further, even with regard to, for example, a lighting fixture using an organic EL panel, application to a portion having a curved surface is under consideration. Specifically, a lighting fixture has been developed in which an organic EL panel is incorporated in a surface of an object having a curved surface such as a roof, a post, an exterior wall, or the like of a building. Therefore, drastic thinning of an organic EL panel used in this kind of a lighting fixture is also promoted from the viewpoint of securing sufficient flexibility.

Here, an organic EL panel has a stacked structure of an anode layer and a cathode layer as supply sources of holes and electrons, respectively, and a light emitting layer sandwiched therebetween and formed of an organic material such as a resin. As a substrate thereof, glass (glass substrate) which is more excellent in gas barrier property compared to a resin is often used. Therefore, in order to make thinner the above-mentioned panel, a glass substrate of this kind is required to be drastically thinner.

By the way, all the above-mentioned electrode layers and organic layer are formed on the order of micrometers or nanometers and very thin. Therefore, there is a tendency that, as means for forming the above-mentioned layers on the glass substrate, film formation treatment means such as physical vapor deposition (PVD) represented by vacuum deposition and sputtering or chemical vapor deposition (CVD) is suitably adopted. Film formation treatment of this kind is generally accompanied with heating of a vapor deposition material to form a film on a member on which vapor deposition is carried out (glass substrate), and hence there are cases where heat generated in the above-mentioned heating heats the glass substrate. For example, in the case of vacuum deposition, by opposing a vapor deposition source to be a heat source to a glass substrate and starting to heat a vapor deposition material, radiant heat is transferred from the vapor deposition source toward the glass substrate. This is because radiant heat may be transferred even through a vacuum. Much of the radiant heat supplied from the vapor deposition source toward the glass substrate in this way except heat dissipated via a portion of the glass substrate which is in contact with a member for supporting the glass substrate is transferred from a front surface of the glass substrate which is on a film formation side to a rear surface thereof, and is dissipated in the vacuum from the rear surface by radiation. Therefore, depending on the magnitude relationship between the amount of heat radiated from the vapor deposition source and the heat capacity of the glass substrate, a situation may occur in which the radiant heat from the vapor deposition source is accumulated in the glass substrate, and as a result, the temperature of the glass substrate rises.

A light emitting layer which forms an organic EL panel is formed of an organic material, and thus is more heat-sensitive and is more liable to be altered and degraded compared to a metal, glass, or the like. Therefore, it is necessary to maintain the temperature of a front surface of the glass substrate in vapor deposition as low as possible (for example, on the order of several tens of degrees centigrade), but, as described above, in recent years, there is a tendency to thin a glass substrate for an organic EL panel more and more. Therefore, as the glass substrate becomes thinner, the heat capacity thereof reduces accordingly, and the temperature of the front surface of the glass substrate in vapor deposition is more liable to rise proportionately, which results in temperature rise of the organic layer including the light emitting layer. As a result, there is a fear that the light emitting layer (organic layer) may be altered and degraded.

The above-mentioned problem is not limited to an organic EL panel. This is a problem which may similarly arises even when a predetermined organic layer is formed on a glass substrate by vapor deposition treatment, or when vapor deposition treatment is carried out on a glass substrate having an organic layer formed thereon.

As means for preventing temperature rise of the glass substrate, ordinarily, a method in which a sufficient distance is secured between the vapor deposition source and the glass substrate (the vapor deposition source is moved away from the glass substrate) is thought of. However, from the viewpoint of the speed of the vapor deposition, the efficiency in the use of the material, limitations on the installation space, and the like, it is by no means desired that the distance between the vapor deposition source and the glass substrate be too large.

For example, Patent Literature 1 given below describes a method in which, a heat dissipating sheet formed of, for example, a silicone rubber, is provided between a resin sheet to be a film formation substrate and a base in a state of being in intimate contact with the resin sheet and the base, and a vapor deposition film is formed on a surface of the resin sheet that is opposite to a side on which the heat dissipating sheet is in intimate contact therewith. Further, Patent Literature 2 given below describes a method in which the surface temperature of a substrate obtained when a thin film is formed is measured, and the temperature of the substrate is controlled based on the measured surface temperature. Specifically, there is described an attempt to control the temperature of the substrate by adjusting discharge source output in sputtering, by passing the substrate between temperature adjustable rolls, or the like. Still further, as described in Patent Literature 3 given below, a method is also proposed in which all the region of a vapor deposition source except for an opening is covered with a heat shield plate having a cooling function to suppress radiant heat which is transferred from the vapor deposition source to a substrate.

### CITATION LIST

### Patent Literature

Patent Literature 1: JP 2009-161829 A
Patent Literature 2: JP 09-59775 A
Patent Literature 3: JP 2005-91345 A

### SUMMARY OF INVENTION

### Technical Problem

Here, in order to brought the heat dissipating sheet described in the above-mentioned Patent Literature 1 into intimate contact with the resin sheet to be the substrate, both the heat dissipating sheet and the resin sheet are required to have hardness (elasticity) appropriate for allowing the intimate contact with each other (see paragraph 0018 of the literature). However, the stiffness of glass is considerably larger than that of the resin, and thus, if a glass substrate is the target of cooling, even when the glass substrate is caused to have flexibility by being thinned, it is difficult to bring the heat dissipating sheet and the glass substrate into intimate contact with each other without a gap therebetween over the whole area of an overlapping portion. If intimate contact without a gap is impossible in this way, air which remains in the gap between the glass substrate and the heat dissipating sheet increases contact thermal resistance between the two (thermal resistance caused by imperfect intimate contact between the glass substrate and the heat dissipating sheet at the overlapping portion), and, as a result, a problem arises that the cooling effect of the heat dissipating sheet becomes smaller. A problem of this kind may similarly arise in the case where the glass substrate is passed between temperature adjustable rolls that is described in the above-mentioned Patent Literature 2.

Further, with regard to a method in which the discharge source output in sputtering is adjusted as described in the above-mentioned Patent Literature 2, excessive heating of the glass substrate may be prevented. However, the output is fluctuated in order to control the temperature of the substrate, and thus it is difficult to form a light emitting layer (an organic layer) or electrode layers with stable quality. Further, if the output is compromised in order to avoid excessive heating, time necessary for the film formation is uselessly extended, which lacks practicality from the viewpoint of productivity.

Similarly, the means for preventing heat transfer described in the above-mentioned Patent Literature 3 does not cause such problems as described above, but, after all, a portion of radiant heat transferred from the vapor deposition source toward the glass substrate which mainly affects the temperature rise of the glass substrate is a portion which contributes to film formation on the glass substrate. Therefore, to cover a region corresponding to the periphery of the surface of the formed film is not a radical measure.

In view of the circumstances described above, a technical problem to be solved in the present specification is to prevent, without compromising productivity, alteration and degradation of an organic layer in vapor deposition treatment by effectively cooling a glass substrate, thereby forming an organic layer of high quality.

### Solution to Problem

The above-mentioned problems are solved by a vapor deposition method according to the present invention. That is, there is provided a vapor deposition method of forming one or a plurality of layers on a one surface side of a glass substrate, the one or the plurality of layers including an organic layer, the vapor deposition method including: forming at least one layer of the one or the plurality of layers by vapor deposition treatment; and in the vapor deposition treatment, bringing one surface of a cooling plate for cooling the glass substrate into direct surface contact with another surface of the glass substrate, and bringing the contact surfaces of the cooling plate and the glass substrate into an intimate contact with each other to an extent of being peelable by the direct surface contact.

Note that, the phrase “bringing one surface of a cooling plate for cooling the glass substrate into direct surface contact with another surface of the glass substrate” as used herein means that the glass substrate and the cooling plate are directly stacked without an adhesive, glass frit, or the like provided therebetween. Further, the phrase “bringing the contact surfaces of the cooling plate and the glass substrate into an intimate contact with each other to an extent of being peelable” means that, as a result of the surface contact described above, a predetermined intimate contact state is formed between the contact surfaces of the glass substrate and the cooling plate to the extent that predetermined peel strength is exerted between the two plates. Further, “predetermined peel strength” as used herein means adhesion at a level at which, in vapor deposition treatment of this kind, the glass substrate and the cooling plate are not peeled away from each other by force which may ordinarily act on the glass substrate and the cooling plate.

Further, the vapor deposition treatment as referred to in the present invention includes physical vapor deposition and chemical vapor deposition. The physical vapor deposition includes vacuum deposition, sputtering, ion plating, molecular beam epitaxy (MBE), and the like.

According to the above-mentioned method, the area in which the glass substrate and the cooling plate are in intimate contact with each other, in other words, true contact area, significantly increases, and thus the substantial heat conduction efficiency (also referred to as heat transfer coefficient) between the glass substrate and the cooling plate may be enhanced. The reason is that, differently from a sheet made of resin or the like, a glass substrate may obtain required flatness and surface roughness even if the glass substrate is thinned by devising a forming method thereof or by devising a polishing method performed after the glass substrate is formed. Therefore, radiant heat from the vapor deposition source which is transferred to the glass substrate may be efficiently transferred to the cooling plate to prevent temperature rise of the glass substrate during the vapor deposition treatment as much as possible. This may prevent alteration and degradation due to temperature rise of the organic layer which is formed on the glass substrate by vapor deposition to secure the quality of the organic layer. Further, when a layer of another kind is formed on the organic layer by vapor deposition, alteration and degradation of the organic layer which is already formed on the glass substrate (or on a layer of still another kind) due to temperature rise may be prevented to secure the quality of the organic layer. Further, by increasing the true contact area to bring the cooling plate into surface contact with the glass substrate as described above, the position of the glass substrate in intimate contact with the cooling plate is stabilized. Therefore, by holding or fixing the cooling plate to a vapor deposition system body with, for example, an appropriate jig, the glass substrate which is a member on which vapor deposition is to be carried out may be supported always at a fixed posture. This enables stable formation of an organic layer or the like by the above-mentioned vapor deposition treatment with high precision. Meanwhile, in the intimate contact state described above, by peeling a part of the glass substrate away from the cooling plate (or by peeling a part of the cooling plate away from the glass substrate), the rest of the glass substrate may be peeled away from the cooling plate in succession, and thus the two may be easily separated after the vapor deposition treatment is completed. Here, the glass substrate and the cooling plate are in direct surface contact with each other without an adhesive or the like therebetween, and hence, the another surface of the glass substrate which is separated from the cooling plate does not have a sticky component which remains thereon. Therefore, the trouble of additionally carrying out cleaning treatment or the like for removing unnecessary things may be saved.

Here, as a result of diligent research by the present inventors, it has been made clear that, in order to form the predetermined intimate contact state between the contact surfaces of the glass substrate and the cooling plate to the extent that predetermined peel strength is exerted between the two plates as a result of the surface contact described above, both of the surfaces in intimate contact with each other are required to be extremely flat. As an example, it has been made clear that, when a glass plate is used as the cooling plate, that is, when glass plates are brought into surface contact with each other, the above-mentioned intimate contact state may be obtained by using, as the glass substrate, a glass substrate having a surface in contact with the cooling plate that has a surface roughness Ra of 2.0 nm or smaller and using, as the cooling plate, a cooling plate having a surface in contact with the glass substrate that has a surface roughness Ra of 2.0 nm or smaller. Such fine surface roughness may be obtained by applying, after the glass plate as a base is formed, predetermined polishing treatment, or may be obtained by forming the glass substrate and the cooling plate by, for example, the downdraw method, in particular, the overflow downdraw method. Note that, the surface roughness Ra as referred to in the present invention is calculated from measurement values of a range of 10 μm×10 μm under measurement conditions of a scan size of 10 μm, a scan rate of 1 Hz, and 512 sample lines using an atomic force microscope (AFM).

As the cooling plate, one formed of a material having the thermal conductivity equivalent to or larger than that of the glass substrate may be used. Characteristics required for the cooling plate are less severe compared to those of the glass substrate, and hence an adjustment to the thermal conductivity due to change in composition or the like may be made relatively easily. This may further enhance the cooling effect of the cooling plate. Note that, the word “equivalent” as used herein is merely used for the purpose of confirming that a case where the thermal conductivity of the cooling plate is slightly smaller than the thermal conductivity of the glass substrate is not excluded. The word “equivalent” used with regard to the thickness of the cooling plate in the following has a similar meaning.

Specifically, it is desired that, as the cooling plate, one having a thermal conductivity of 0.1 W/m·k or larger and 500 W/m·k or smaller be used. The reason is that, when heat dissipating action required for the cooling plate itself is taken into consideration, a thermal conductivity of at least on the order of 0.1 W/m·k is necessary.

Further, as the cooling plate, one having a thickness which is equivalent to or larger than that of the glass substrate may be used. The cooling plate itself is not different in that heat transferred from the glass substrate is accumulated therein, and hence by increasing the thickness to increase the heat capacity of the cooling plate itself, heat transferred from the glass substrate may be prevented from going back to the glass substrate without fail.

Specifically, it is desired that, as the cooling plate, one having a thickness of 100 μm or larger and 1500 μm or smaller be used. The reason is that, if the cooling plate is too thin (thinner than 100 μm), it is difficult to secure a minimum required heat capacity of the cooling plate, and further, the surface contact with the glass substrate and the separating operation from the glass substrate after the vapor deposition may be hindered (the workability may be reduced).

It is desired that the cooling plate be a glass plate or a metal plate. The reason is that, if the cooling plate is made of such a material, the above-mentioned thermal conductivity may be satisfied, and the flatness of a region of the cooling plate to be a contact surface may be easily improved by treatment such as polishing (if the cooling plate is a glass plate, the above-mentioned surface roughness may be attained with ease). Further, by forming the cooling plate of a material similar to that of the glass substrate, an advantage that the intimate contact between the two is further improved may be expected.

In contrast to the cooling plate having the structure described above, as the glass substrate, one having a thickness of, for example, 10 μm or larger and 700 μm or smaller, preferably 300 μm or smaller, may be used. Further, in this case, a glass substrate having a thermal conductivity of 0.1 W/m·k or larger and 1.5 W/m·k or smaller may be used. Here, the minimum value of the thickness of the glass substrate is 10 μm because, if the glass substrate is thinner, reduction of work efficiency due to insufficient strength or obvious flexure is inevitable. On the other hand, if the thickness of the glass substrate 700 μm or smaller, in particular, 300 μm or smaller, sufficient flexibility may manifest itself in an organic EL panel having the glass substrate incorporated therein or an image display device, lighting fixture, or the like including the organic EL panel. Further, the thermal conductivity is 0.1 W/m·k or larger because, if the thermal conductivity is smaller, even if a cooling plate which is excellent in cooling efficiency is in surface contact in the above-mentioned mode, it is difficult to transfer radiant heat which is transferred to the one surface to be a film formation side through the glass substrate to the another surface to be on the intimate contact side with the cooling plate.

The vapor deposition method described above may be suitably used in, for example, vapor deposition treatment of an organic layer or an electrode layers in an organic EL panel. Specifically, the plurality of layers formed on the one surface side of the glass substrate may be a stacked body formed of an anode and a cathode, both of which are layer-like, and one or more organic layers which intervene between the two electrodes. Further, in this case, the stacked body and the glass substrate may form the organic EL panel. In vapor deposition treatment of this kind, vacuum deposition, sputtering, or the like having the amount of radiant heat relatively large tends to be used as the vapor deposition means, and hence, when an electrode layer (cathode layer) formed of a metal material made of a material such as aluminum or silver is formed on an organic layer such as a light emitting layer, the temperature of the glass substrate easily rises, which may easily lead to alteration and degradation of the organic layer that is already formed on the glass substrate. However, the vapor deposition method according to the present invention may avoid a problem of this kind and an organic EL panel including an organic layer of high quality may be mass-produced.

Further, the above-mentioned problems are also solved by a vapor deposition system according to the present invention. That is, there is provided a vapor deposition system for forming by vapor deposition treatment, among one or a plurality of layers formed on a one surface side of a glass substrate, the one or the plurality of layers including an organic layer, at least one layer of the one or the plurality of layers, the vapor deposition system including a cooling plate for cooling the glass substrate in the vapor deposition treatment, in which one surface of the cooling plate is brought into direct surface contact with another surface of the glass substrate, and the contact surfaces of the cooling plate and the glass substrate are brought into an intimate contact with each other to an extent of being peelable by the direct surface contact.

The above-mentioned vapor deposition system also has the same technical characteristics as those of the vapor deposition method described at the beginning of this section, and thus may obtain the same action and effect as those of the above-mentioned vapor deposition method.

### Advantageous Effects of Invention

As described above, the vapor deposition method and the vapor deposition system according to the present invention may prevent alteration and degradation of the organic layer in vapor deposition treatment without compromising productivity by effectively cooling the glass substrate, thereby forming an organic layer of high quality.

### BRIEF DESCRIPTION OF DRAWINGS

FIG. 1 A sectional view illustrating a structure in section of a principal part of an organic EL panel according to an embodiment of the present invention.

FIG. 2 A conceptual view for conceptually describing a process of forming a cathode layer on an organic layer by vapor deposition in a manufacturing process of the organic EL panel illustrated in FIG. 1.

FIG. 3 A sectional view illustrating a state in which the organic EL panel before the cathode layer is formed thereon in the vapor deposition process illustrated in FIG. 2 and a cooling plate are in intimate contact with each other in a predetermined mode.

### DESCRIPTION OF EMBODIMENT

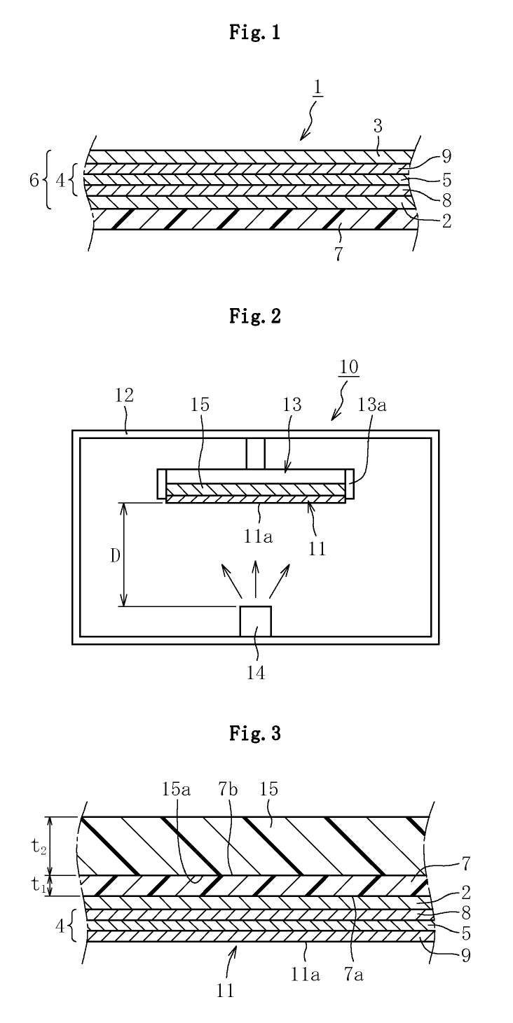

An embodiment of the present invention is described with reference to FIGS. 1 to 3.

FIG. 1 is a sectional view illustrating a structure in section of a principal part of an organic EL panel 1 according to the embodiment of the present invention. As illustrated in the figure, the organic EL panel 1 includes a stacked body 6 formed of an anode layer 2 and a cathode layer 3 which are a pair of electrode layers and an organic layer 4 including a light emitting layer 5, and a glass substrate 7 having the stacked body 6 mounted on one surface 7a thereof. The stacked body 6 has a stacked structure in which the organic layer 4 is sandwiched between the anode layer 2 and the cathode layer 3, and exhibits a structure in which the anode layer 2, the organic layer 4, and the cathode layer 3 are stacked in this stated order from a side nearer to the glass substrate 7. Further, in this illustrated example, the organic layer 4 has the light emitting layer 5 in the middle thereof, and a hole transport layer 8 and an electron transport layer 9 on both sides, respectively, of the light emitting layer 5. In this case, the stacked body 6 exhibits a structure in which the anode layer 2, the hole transport layer 8, the light emitting layer 5, the electron transport layer 9, and the cathode layer 3 in this stated order from the side nearer to the glass substrate 7. In the following, the structures of the respective layers are described.

The anode layer 2 plays a role in injecting holes in the hole transport layer, and, for example, a material exhibiting a work function of 4.5 eV or higher is suitably used therefor. Further, ordinarily, the glass substrate 7 side is alight emitting surface, and thus a material which is permeable to light (which has a high transmittance) is suitably used. Here, a material to be used for the anode layer 2 is, for example, an inorganic material, in particular, an inorganic oxide. Specific examples thereof include metals, alloys, and oxides, such as indium oxide, zinc oxide, indium tin oxide (ITO), indium zinc oxide (IZO), tin oxide (NESA), gold, silver, platinum, copper, and aluminum, and mixtures thereof.

Note that, the thickness of the anode layer 2 may be appropriately selected taking into consideration the permeability to light and the electrical conductivity, and is set, for example, in a range of 5 nm or larger and 10 μm or smaller, preferably in a range of 10 nm or larger and 1 μm or smaller, and more preferably in a range of 20 nm or larger and 500 nm or smaller.

The cathode layer 3 plays a role in injecting electrons in the electron transport layer, and, for example, a material which has a small work function and which facilitates injection of electrons in the electron transport layer is suitably used therefor. A material having a high electrical conductivity may also be suitably used, and a material having a high visible light reflectance may also be used. Specific examples thereof include alkali metals, alkaline earth metals, and transition metals, such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium, gold, silver, platinum, copper, manganese, titanium, cobalt, nickel, tungsten, and tin, an alloy including at least one kind of those metals, and graphite and a graphite interlayer compound. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy. Further, a transparent conductive electrode may also be used as the cathode, such as the above-mentioned conductive metal oxide, e.g., indium oxide, zinc oxide, tin oxide, ITO, or IZO, or a conductive organic substance.

Note that, the thickness of the cathode layer 3 may be appropriately selected taking into consideration the electrical conductivity and the durability, and is set, for example, in a range of 10 nm or larger and 10 μm or smaller, preferably in a range of 20 nm or larger and 1 μm or smaller, and more preferably in a range of 50 nm or larger and 500 nm or smaller.

The light emitting layer 5 which forms the organic layer 4 is a layer including a light emitting material, and, ordinarily, an organic compound which emits fluorescence or phosphorescence is mainly used as the light emitting material. Generally, insofar as being a material used as the light emitting material, an arbitrary light emitting material may be used whether the material is a low molecular compound or a high molecular compound. More specifically, the following dye-based material, metal complex-based material, and polymer-based material may be given. Note that, a dopant material may be further included in the light emitting layer formed of those organic compounds.

Examples of the dye-based material include a cyclopendamine derivative, a tetraphenylbutadiene derivative compound, a triphenylamine derivative, an oxadiazole derivative, a pyrazoloquinoline derivative, a distyrylbenzene derivative, a distyrylarylene derivative, a pyrrole derivative, a thiophene ring compound, a pyridine ring compound, a perinone derivative, a perylene derivative, an oligothiophene derivative, a trifumanylamine derivative, an oxadiazole dimer, and a pyrazoline dimer. Further, examples of the metal complex-based material include metal complexes that emit light from an excited triplet state, such as an iridium complex and a platinum complex, an aluminum quinolinol complex, a benzoquinolinol beryllium complex, a benzoxazolyl zinc complex, a benzothiazole zinc complex, an azomethyl zinc complex, a porphyrin zinc complex, and a europium complex. Further, other examples of the metal complex-based material include metal complexes each having, as a central metal, Al, Zn, Be, a rare earth metal such as Tb, Eu, or Dy, or the like and having, as a ligand, an oxadiazole structure, a thiadiazole structure, a phenylpyridine structure, a phenylbenzimidazole structure, a quinoline structure, or the like. Meanwhile, examples of the polymer-based material include a distyrylarylene derivative, an oxadiazole derivative, a polyparaphenylenevinylene derivative, a polythiophene derivative, a polyparaphenylene derivative, a polysilane derivative, a polyacetylene derivative, a polyfluorene derivative, a polyvinylcarbazole derivative, a quinacridone derivative, a coumarin derivative, and polymerized products, i.e., polymers of the above-mentioned dye materials, metal complex-based light emitting materials, and the like.

A material forming the hole transport layer 8 is not specifically limited insofar as the material facilitates movement of holes to the light emitting layer 5, and a publicly known material may be used. For example, a hole transport material used in the present invention is not specifically limited, and any compound which is ordinarily used as a hole transport material may be used. Examples thereof include aromatic amine derivatives typified by triphenyldiamines such as bis (di(p-tolyl)aminophenyl)-1,1-cyclohexane [13], TPD [11], and N,N′-diphenyl-N-N-bis (1-naphthyl)-1,1′-biphenyl)-4,4′-diamine (NPB) [14], polyvinylcarbazole or a derivative thereof, polysilane or a derivative thereof, a polysiloxane derivative having an aromatic amine in a side chain or main chain thereof, a pyrazoline derivative, an arylamine derivative, a stilbene derivative, a triphenyldiamine derivative, polyaniline or a derivative thereof, polythiophene or a derivative thereof, a polyarylamine or a derivative thereof, polypyrrole or a derivative thereof, poly(p-phenylenevinylene) or a derivative thereof, and poly(2,5-thienylenevinylene) or a derivative thereof.

A known material may be used as a material for constructing the electron transport layer 9, and examples thereof include oxadiazole derivatives such as 2-(4-biphenylyl)-5-(4-t-butylphenyl)-1,3,4-oxadiazole (Bu-PBD) [18] and OXD-7 [3], triazole derivatives (such as [19] and [20]), anthraquinodimethane or a derivative thereof, benzoquinone or a derivative thereof, naphthoquinone or a derivative thereof, anthraquinone or a derivative thereof, tetracyanoanthraquinodimethane or a derivative thereof, a fluorenone derivative, diphenyldicyanoethylene or a derivative thereof, a diphenoquinone derivative, a metal complex of 8-hydroxyquinoline or a derivative thereof, polyquinoline or a derivative thereof, polyquinoxaline or a derivative thereof, and polyfluorene or a derivative thereof.

A method of forming the layers which form the organic layer 4 is not specifically limited. Insofar as at least one layer of the above-mentioned layers is formed by physical vapor deposition or chemical vapor deposition described above, means for forming the other layers is arbitrary. For example, in addition to the various kinds of vapor deposition described above, forming means by various kinds of applying methods including dipping, spin coating, bar coating, and roll coating may be adopted. Here, the thicknesses of the layers described above are, for example, set in a range of 1 nm or larger and 1000 nm or smaller.

The glass substrate 7 may be formed of a known glass material such as silicate glass, silica glass, or borosilicate glass, or may be formed of non-alkali glass. Here, the “non-alkali glass” refers to glass that is substantially free of an alkali component (alkali metal oxide), and specifically, to glass in which the content of the alkali component is 1000 ppm or less, preferably 500 ppm or less, more preferably 300 ppm or less. An example of usable non-alkali glass is “OA-10G” manufactured by Nippon Electric Glass Co., Ltd. If an alkali component is contained in the glass substrate 7, alkali ions substitute for hydrogen ions on the surface, and thus the structure of the glass substrate 7 becomes coarse and the glass substrate 7 is more liable to be broken due to degradation over time. By using non-alkali glass, a problem of this kind may be avoided.

Means for forming the glass substrate 7 is not specifically limited, but, as described below, in order to attain a required intimate contact state with a cooling plate 15, forming means or treating means for, for example, suppressing the surface roughness Ra of the glass substrate 7 within a predetermined value may be adopted. More specifically, in order to set the surface roughness Ra of another surface 7b of the glass substrate 7 which is on the side in intimate contact with the cooling plate 15 to be 2.0 nm or smaller, the glass substrate 7 may undergo precision polishing or the like. Alternatively, by using one formed by the downdraw method, in particular, the overflow downdraw method, the above-mentioned surface roughness may be obtained without precision polishing or the like.

In the following, a vapor deposition process according to the present invention is described taking as an example a case where the cathode layer 3 is formed by vacuum deposition which is a kind of physical vapor deposition on the one surface 7a side of the glass substrate 7 that forms the organic EL panel 1.

FIG. 2 is a view for describing an overview of a method of manufacturing the organic EL panel 1 according to the embodiment of the present invention, and is a schematic diagram of a vapor deposition system (vacuum vapor deposition system) 10 for forming by vacuum deposition on the light emitting layer 5 the cathode layer 3 which forms the stacked body 6. As illustrated in the figure, the vapor deposition system 10 is a so-called resistance heating vacuum vapor deposition system, and includes a vacuum chamber 12, a retaining mechanism 13 provided in the vacuum chamber 12 for retaining an organic EL panel before the cathode layer 3 is formed thereon (hereinafter, simply referred to as a material 11), a vapor deposition source 14 for heating a vapor deposition material and supplying the vapor deposition material to a predetermined surface of the material 11 which is the member on which vapor deposition is to be carried out, and a cooling plate 15 for cooling the glass substrate 7 of the material 11.

The vapor deposition system 10 further includes a vacuum pump (evacuating means) for evacuating the vacuum chamber 12 to attain a predetermined vacuum (for example, a vacuum on the order of 1×10⁻⁵ Pa to 1×10⁻² Pa) and gas introducing means for introducing predetermined gas into the vacuum chamber, both of which are not illustrated.

The retaining mechanism 13 is provided for the purpose of retaining the material 11 of the organic EL panel 1 in vapor deposition, and here, has a retaining portion 13a for retaining the glass substrate 7 located on one end side of the material 11, or, as described below, the cooling plate 15 in intimate contact with the glass substrate 7 by surface contact in a predetermined mode. Here, the form of the retaining portion 13a is not specifically limited. For example, as illustrated in the figure, a chuck mechanism for chucking a peripheral side surface of the cooling plate 15 with a pair of claws, a suction mechanism for sucking the other surface (a surface opposite to the glass substrate 7 side) of the cooling plate 15, or the like may be adopted. Although not illustrated in the figure, if a vapor deposition surface 11a to be described below is partly masked, a mechanism for collectively chucking the glass substrate 7 and the cooling plate 15 by sandwiching the masked portion in a thickness direction may be adopted. Further, as illustrated in the figure, the retaining mechanism 13 may include a mechanism which rotates about a rotation shaft provided so as to be upright with respect to the glass substrate 7 and the cooling plate 15. In that case, although not illustrated in the figure, the vapor deposition source 14 to be described below may be located off center with respect to an extended line of the rotation shaft. When the vapor deposition source 14 is located off center in this way, a plurality of vapor deposition sources 14 may be provided.

The vapor deposition source 14 is provided in a lower portion of the vacuum chamber 12 and at a position opposed to the vapor deposition surface 11a of the material 11 retained by the retaining mechanism 13 (here, as illustrated in FIG. 3, a surface of the electron transport layer 9 forming the organic layer 4 which is opposite to the light emitting layer 5 side). The vapor deposition source 14 has a function of vaporizing the vapor deposition material by heating, and is configured to heat and vaporize the vapor deposition material such as aluminum or magnesium contained in a crucible by, for example, a resistance heating device (not shown). Of course, the means for heating and vaporizing the vapor deposition material is not limited to the above-mentioned means, and various kinds of publicly known heating and vaporizing means may be used. In this case, a distance D between the vapor deposition source 14 and the vapor deposition surface 11a of the material 11 is set in an appropriate range (for example, 100 mm or larger and 500 mm or smaller) taking into consideration vapor deposition speed, efficiency in the use of the vapor deposition material, and the like.

The cooling plate 15 is provided for the purpose of cooling the material 11 of the organic EL panel 1 in vapor deposition, and is retained by the retaining mechanism 13 as described above. Alternatively, as described below, the glass substrate 7 (material 11) is retained via the cooling plate 15 by being retained by the retaining mechanism 13 in an intimate contact state with the material 11 which is the member on which vapor deposition to be is carried out as described below. One surface 15a of the cooling plate 15 retained in this way is brought into direct surface contact with the another surface 7b (surface opposite to the anode layer 2 side) of the glass substrate 7 which is located on the outermost side of the material 11 as illustrated in FIG. 3, thereby bringing the contact surfaces into an intimate contact state with each other to the extent of being peelable. Here, the whole of the another surface 7b of the glass substrate 7 is brought into surface contact with the one surface 15a of the cooling plate 15 to attain the above-mentioned intimate contact state.

In order to attain the above-mentioned intimate contact state between the cooling plate 15 and the glass substrate 7, it is preferred that both the flatness of the another surface 7b of the glass substrate 7 and the flatness of the one surface 15a of the cooling plate 15 into direct surface contact be increased to a predetermined level. For example, when the cooling plate 15 is made of glass, it is preferred that both the surface roughness Ra of the another surface 7b of the glass substrate 7 and the surface roughness Ra of the one surface 15a of the cooling plate 15 be set to be 2.0 nm or smaller. The glass substrate 7 and the cooling plate 15 having such a surface roughness Ra may be obtained by precision polishing or the like of glass plates to be the base thereof. Alternatively, if, as the glass plates to be the base, glass plates formed by the downdraw method, in particular, the overflow downdraw method, are used, the above-mentioned surface roughness may be obtained without precision polishing or the like.

Here, an overview of the overflow downdraw method is described in brief. First, a glass ribbon is caused to flow down from a lower end portion of a forming body which is in the shape of a wedge in section, and the glass ribbon which flows down is drawn downward with shrinkage thereof in a width direction being controlled by a cooled roller, thereby forming the glass ribbon at a predetermined thickness. Next, the glass ribbon which attains the predetermined thickness is introduced into a lehr which is provided further downstream to gradually cool the glass ribbon and relieve thermal strain on the glass ribbon. Then, the glass ribbon is cut to obtain a glass plate of predetermined dimensions. As described above, the overflow downdraw method is a forming method in which both surfaces of the glass plate are not brought into contact with a forming member in forming, and thus the both surfaces of the glass plate are less susceptible to flaws and a glass plate having a high-quality surface (surface roughness) may be easily obtained without application of aftertreatment such as polishing.

By bringing the glass substrate 7 and the cooling plate 15 into direct surface contact with each other in this way, the area in which the glass substrate 7 and the cooling plate 15 are in intimate contact with each other, to be precise, the true contact area, significantly increases. Therefore, the substantial heat conduction efficiency (also referred to as heat transfer coefficient) between the glass substrate 7 and the cooling plate 15 may be enhanced and radiant heat from the vapor deposition source 14 which is transferred to the glass substrate 7 may be efficiently dissipated into the cooling plate 15 to prevent temperature rise of the glass substrate 7 during the vapor deposition treatment as much as possible. If temperature rise of the glass substrate 7 may be prevented in this way, a situation in which radiant heat is accumulated in the anode layer 2 and the organic layer 4 which are formed on the side of the one surface 7a of the glass substrate 7 may be avoided as much as possible, and thus alteration and degradation due to temperature rise of the organic layer 4 may be prevented to secure the quality of the organic layer 4. Further, by increasing the true contact area to bring the cooling plate 15 into surface contact with the glass substrate 7 as described above, the posture of the glass substrate 7 in intimate contact with the cooling plate 15 is stabilized. Therefore, by fixing the cooling plate 15 to the body of the vapor deposition system 10 with the retaining mechanism 13, the glass substrate 7 which is a member on which vapor deposition is to be carried out may be retained at a predetermined location and posture with respect to the vapor deposition source 14. This enables stable formation of the organic layer 4, the electrode layers (the anode layer 2 and the cathode layer 3), and the like by the above-mentioned vapor deposition treatment with high precision.

Meanwhile, in the intimate contact state as described above, by peeling a part (peripheral portion) of the glass substrate 7 away from the cooling plate 15 (or, by peeling a part of the cooling plate 15 away from the glass substrate 7), the rest of the glass substrate 7 may be peeled away from the cooling plate 15 in succession, and thus the two may be easily separated after the vapor deposition treatment is completed. Further, here, the glass substrate 7 and the cooling plate 15 are in direct surface contact with each other without an adhesive or the like therebetween, and hence the another surface 7b of the glass substrate 7 which is separated from the cooling plate 15 does not have a sticky component which remains thereon. Therefore, the trouble of additionally carrying out cleaning treatment or the like for removing unnecessary things may be saved with regard to both the glass substrate 7 and the cooling plate 15, and further, the cooling plate 15 may be repeatedly used.

Further, when the cooling plate 15 is a glass plate as described above, the area in which the glass substrate 7 and the cooling plate 15 are in intimate contact with each other (true contact area) tends to increase as both the surface roughness Ra of the another surface 7b of the glass substrate 7 and the surface roughness Ra of the one surface 15a of the cooling plate 15 which are in intimate contact with each other become smaller. For such a reason, the surface roughness Ra of both of the two surfaces 7b and 15a is preferably 1.0 nm or smaller, more preferably 0.5 nm or smaller, and still more preferably 0.2 nm or smaller.

Here, when the thermal conductivity required for the cooling plate 15 is taken into consideration, as the cooling plate 15, one having a thermal conductivity which is equivalent to or larger than that of the glass substrate 7 is preferred. By using the cooling plate 15 formed of such a material, the cooling effect of the cooling plate 15 may be further enhanced. More specifically, it is desired that, as the cooling plate 15, one having a thermal conductivity of 0.1 W/m·k or larger and 500 W/m·k or smaller be used. The reason is that, when heat dissipating action required for the heat cooling plate 15 itself is taken into consideration, a thermal conductivity of at least on the order of 0.1 W/m·k is necessary.

Further, when the thickness required for the cooling plate 15 is taken into consideration, as the cooling plate 15, one having a thickness which is equivalent to or larger than that of the glass substrate 7 is preferred (in FIG. 3, a case where a thickness t₂ of the cooling plate 15 is larger than a thickness t₁ of the glass substrate 7 is illustrated). As the thickness t₂ becomes larger, the heat capacity of the cooling plate 15 itself increases, and hence the situation in which heat transferred from the glass substrate 7 to the cooling plate 15 goes back to the glass substrate 7 from the cooling plate 15 may be prevented without fail. More specifically, it is desired that, as the cooling plate 15, one having the thickness t₂ of 100 μm or larger and 1500 μm or smaller be used. The reason is that a minimum required heat capacity of the cooling plate 15 has to be secured.

Exemplary materials of the cooling plate 15 which satisfy (is more likely to satisfy) the above-mentioned characteristics include glass and metals. If the cooling plate 15 is made of such a material, the above-mentioned thermal conductivity may be satisfied, and the flatness of the regions to be the contact surfaces of the two surfaces 7b and 15a which are in direct surface contact with each other may be easily improved by treatment such as polishing (if the cooling plate 15 is a glass plate, the above-mentioned surface roughness may be attained with ease).

Here, when the cooling plate 15 is made of glass, similarly to the glass substrate 7, the cooling plate 15 may be formed of a publicly known glass material such as silicate glass, silica glass, or borosilicate glass, or, may be formed of non-alkali glass. Further, in this case, it is desired that the cooling plate 15 be formed of glass having the same composition as that of the glass substrate 7 (glass of the same kind as that of the glass substrate 7). When the glass substrate 7 is formed of non-alkali glass, it is most preferred that the cooling plate 15 be formed of non-alkali glass. By forming the cooling plate 15 of glass of the same kind as that of the glass substrate 7, even in this embodiment in which vacuum deposition is carried out in a state in which the two plates 7 and 15 are brought into direct surface contact with each other and in an intimate contact with each other to the extent of being peelable, partial peeling of the glass substrate 7 away from the cooling plate 15 or the like due to difference between thermal expansion coefficients of the two plates may be effectively prevented. Therefore, the intimate contact state of the two plates during the vapor deposition treatment may be maintained and the high effect of cooling the glass substrate 7 of the cooling plate 15 may be obtained with stability.

With respect to the cooling plate 15 having the above-mentioned structure, as the glass substrate 7, for example, one having the thickness t₁ of 10 μm or larger and 700 μm or smaller, preferably 300 μm or smaller, may be used. Further, in this case, one having a thermal conductivity of 0.1 W/m·k or larger and 1.5 W/m·k or smaller may be used. Here, by setting the thickness t₁ of the glass substrate 7 to 10 μm or larger, while thinning is attained, minimum required strength and handling ability may be secured. On the other hand, if the thickness t₁ of the glass substrate 7 is 700 μm or smaller, in particular, 300 μm or smaller, sufficient flexibility may manifest itself in the organic EL panel 1 having the glass substrate 7 incorporated therein or in an image display device, lighting fixture, or the like including the organic EL panel 1. Further, the thermal conductivity of at least 0.1 W/m·k of the glass substrate 7 makes it possible to transfer radiant heat which is transferred to the one surface 7a to be the film formation side through the glass substrate 7 to the another surface 7b to be on the intimate contact side with the cooling plate 15 to enjoy the cooling effect of the cooling plate 15.

Note that, in order for the cooling plate 15 to exert the best possible effect of cooling the glass substrate 7, it is preferred that the whole of the another surface 7b of the glass substrate 7 be the contact surface with the one surface 15a of the cooling plate 15. Alternatively, when importance is placed on separability from the cooling plate 15 (work efficiency) after the vapor deposition treatment, the contact surfaces of the glass substrate 7 and the cooling plate 15a may be caused to be coincident with each other or a peripheral portion of the glass substrate 7 may be caused to protrude from the cooling plate 15 by, for example, making the glass substrate 7 a little larger than the cooling plate 15.

In the above, the vapor deposition method and the vapor deposition system according to the embodiment of the present invention are described, but of course the vapor deposition method and the vapor deposition system are not limited to those of the above-mentioned exemplary embodiment and may take an arbitrary form which falls within the scope of the present invention.

For example, in the above-mentioned embodiment, a case where the cathode layer 3 is formed by vapor deposition on the material 11 having the anode layer 2 and the organic layer 4 formed on the glass substrate 7 is described as an example, but of course, the method and the system according to the present invention may be applied when other layers, for example, the anode layer 2 and layers which form the organic layer 4 (the light emitting layer 5, the hole transport layer 8, the electron transport layer 9, and the like, and a hole injection layer and an electron injection layer described below are also included) are formed by vapor deposition.

Further, in the above-mentioned embodiment, a case where the stacked body 6 having the following structure is formed is described as an example. That is, the stacked body 6 has the structure in which the organic layer 4 having the light emitting layer 5 in the middle thereof and the hole transport layer 8 and the electron transport layer 9 on both sides of the light emitting layer 5, respectively, intervenes between the anode layer 2 and the cathode layer 3. However, the present invention is not limited to this structure. The structure of the stacked body 6 is arbitrary, and the number of stacked layers therein and the order of stacking the layers therein may be freely set insofar as the organic EL panel 1 may be formed. For example, the organic layer 4 which intervenes between the anode layer 2 and the cathode layer 3 may be formed of only the light emitting layer 5, or may be formed of two layers of the light emitting layer 5 and the hole transport layer 8 or the light emitting layer 5 and the electron transport layer 9. Further, the light emitting layer 5 included in the organic layer 4 is not limited to a single-layer one. For example, a plurality of light emitting layers 5 or a light emitting layer 5 formed of a material other than an organic material together with the light emitting layer 5 formed of an organic material may be included in the organic layer 4. Further, the organic layer 4 may include, other than the above-mentioned layers 5, 8, and 9, other layers such as a hole injection layer or an electron injection layer. In this case, there may be employed a mode in which the hole injection layer intervenes, for example, between the anode layer 2 and the light emitting layer 5, or between the anode layer 2 and the hole transport layer 8. Similarly, there may be employed a mode in which the electron injection layer intervenes, for example, between the cathode layer 3 and the light emitting layer 5, or between the cathode layer 3 and the electron transport layer 9.

Further, in the above description, a case where the organic layer 4 and the electrode layers (the anode layer 2 and the cathode layer 3) which form the organic EL panel 1 are formed by vapor deposition is described as an example, but of course, the present invention is not limited thereto. Insofar as one or a plurality of layers are formed on the side of the one surface of the glass substrate, the layer(s) has (have) an organic layer, and at least one kind of the layer(s) is formed by the vapor deposition treatment, a target on which vapor deposition is carried out and a target which is to be vapor deposited are arbitrary. For example, the vapor deposition method or the vapor deposition system according to the present invention may be applied to formation by vapor deposition of a color filter on a glass substrate in a liquid crystal display.

Further, even with respect to points other than the above-mentioned points, other specific form may of course be taken insofar as the technical significance of the present invention is not lost.

### Examples

In the following, an experiment which was conducted by the present inventors in order to prove the usefulness of the present invention is described. In this experiment, the surface temperature on a film formation side of a glass substrate in vapor deposition was measured both in a case where a cooling plate was in intimate contact with the glass substrate in a predetermined mode and in a case where a cooling plate was not used to evaluate the usefulness of the present invention.

More specifically, as shown in Table 1 given below, after thin films corresponding to the anode layer and the organic layer (light emitting layer) were formed on one surface of a glass substrate, film formation treatment corresponding to formation of the cathode layer was carried out by vacuum deposition. Further, the temperature of the surface on the film formation side of the glass substrate during the vapor deposition treatment was measured by affixing a thermolabel (manufactured by Nichiyu Giken Kogyo Co., Ltd.) to the surface. This experiment was conducted for the respective glass substrates having different thicknesses. With regard to the respective thicknesses, the experiment was also conducted in the case where the cooling plate according to the present invention was brought into intimate contact with the glass substrate in the predetermined mode.

Here, as the glass substrate, non-alkali glass “OA-10G” (thermal conductivity: 1 W/m·k) manufactured by Nippon Electric Glass Co., Ltd. was used. Irrespective of the thickness, all the glass substrates used was formed to be 50 mm×50 mm. The surface roughness Ra of the surface on the film formation side was 1.0 nm with regard to all the glass substrates.

As the cooling plate, similarly to the above, a glass substrate (OA-10G) was used. The thickness was 0.7 mm. The dimensions of the surface were similar to the case of the above-mentioned glass substrates (50 mm×50 mm). The surface roughness Ra of the surface of the cooling plate in intimate contact with the glass substrate was 1.0 nm.

On one surface of the above-mentioned glass substrate, an indium tin oxide alloy (ITO) was formed into a film as an anode layer so as to have a thickness of 150 nm. After that, the above-mentioned substrate having formed thereon the anode layer was mounted on a resistance heating vacuum deposition apparatus, and, on the ITO (anode layer), 4,4′-bis[N-(naphtyl)-N-phenyl-amino]biphenyl (α-NPD) was formed into a film as a hole injection layer at a deposition rate of 0.1 nm/sec so as to have a thickness of 50 nm under a degree of vacuum of 5×10⁻⁵ Pa. In addition, on the hole injection layer, tris(8-quinolinol)aluminum (Alq3) was co-deposited with 5 wt % of rubrene to be formed into a film as a light emitting layer at a deposition rate of 0.1 nm/sec so as to have a thickness of 40 nm. In addition, on the light emitting layer, Alq3 was formed into a film as an electron transport layer at a deposition rate of 0.1 nm/sec so as to have a thickness of 30 nm. In addition, on the electron transport layer, LiF was formed into a film so as to have a thickness of 0.5 nm.

Finally, aluminum was formed into a film as a cathode layer with a resistance heating vacuum deposition apparatus, as in the foregoing, at a deposition rate of 0.5 nm/sec so as to have a thickness of 100 nm (300 nm only in the case where the thickness of the glass substrate was 0.7 mm). Here, a crucible made of silica and a crucible made of aluminum nitride were used for the film formation of the above-mentioned organic layer and the film formation of the cathode layer, respectively. A distance between the above-mentioned deposition source and the surface of the glass substrate on the side of the film formation was uniformly set to 250 nm. Other conditions are as shown in Table 1 below.

TABLE 1

| | Example | Example | Example | Comparative | Comparative | Comparative | Comparative |
|---|---|---|---|---|---|---|---|
| | 1 | 2 | 3 | Example 1 | Example 2 | Example 3 | Example 4 |
| Thickness (glass | 0.05 | 0.1 | 0.7 | 0.05 | 0.1 | 0.2 | 0.7 |
| substrate) [mm] | | | | | | | |
| Thickness (cooling | 0.7 | 0.7 | 0.7 | — | — | — | — |
| plate) [mm] | | | | | | | |
| Vapor deposition | 5 | 5 | 5 | 5 | 5 | 5 | 5 |
| speed [Å/sec] | | | | | | | |
| Film thickness [nm] | 100 | 100 | 300 | 100 | 100 | 100 | 300 |
| Current [A] | 200 | 200 | 200 | 200 | 200 | 200 | 200 |
| Voltage [V] | 4 | 4 | 4 | 4 | 4 | 4 | 4 |
| Output [W] | 800 | 800 | 800 | 800 | 800 | 800 | 800 |
| Maximum measured | 65 | 55 | 50 | 115 | 120 | >95 | 80 |
| temperature [° C.] | | | | | | | |

The result of temperature measurement in the vapor deposition, specifically, the maximum measured temperature in the respective vapor depositions are shown in the lowest row of Table 1 given above. As can be seen from the table, when the cooling plate was not used, irrespective of the thickness of the glass substrate, the measured temperature indicated was always high. Further, there can be observed a tendency that, as the thickness became smaller, the measured temperature became higher. On the other hand, when, as in the present invention, the cooling plate was brought into intimate contact with the glass substrate in the predetermined mode, specifically, when the cooling plate was in direct surface contact with the glass substrate and the surface contact brought the contact surfaces into an intimate contact with each other to the extent of being peelable, irrespective of the thickness of the glass substrate, no temperature rise due to radiant heat was observed during the vapor deposition. In other words, a cooling effect to a certain extent of the cooling plate was confirmed.

### REFERENCE SIGNS LIST

1 organic EL panel
2 anode layer
3 cathode layer
4 organic layer
5 light emitting layer
6 stacked body
7 glass substrate
7a one surface (stacked body side)
7b another surface (cooling plate side)
8 hole transport layer
9 electron transport layer
10 vapor deposition system
11 material
11a vapor deposition surface
12 vacuum chamber
13 retaining mechanism
13a retaining portion
14 vapor deposition source
15 cooling plate
15a one surface (glass substrate side)
D distance
t₁ thickness (glass substrate)
t₂ thickness (cooling plate)

1. A vapor deposition method of forming one or a plurality of layers on a one surface side of a glass substrate, the one or the plurality of layers comprising an organic layer, the vapor deposition method comprising:
forming at least one layer of the one or the plurality of layers by vapor deposition treatment; and
in the vapor deposition treatment, bringing one surface of a cooling plate for cooling the glass substrate into direct surface contact with another surface of the glass substrate, and bringing the contact surfaces of the cooling plate and the glass substrate into an intimate contact with each other to an extent of being peelable by the direct surface contact.

2. A vapor deposition method according to claim 1, wherein the one or the plurality of layers comprise a stacked body formed of an anode and a cathode, both of which are layer-like, and one or more of the organic layers which intervene therebetween, the stacked body and the glass substrate forming an organic electroluminescence panel.

3. A vapor deposition method according to claim 1, wherein, as the cooling plate, a cooling plate formed of a material having a thermal conductivity which is equivalent to or larger than a thermal conductivity of the glass substrate is used.

4. A vapor deposition method according to claim 3, wherein, as the cooling plate, a cooling plate having a thermal conductivity of 0.1 W/m·k or larger and 500 W/m·k or smaller is used.

5. A vapor deposition method according to claim 1, wherein, as the cooling plate, a cooling plate having a thickness which is equivalent to or larger than a thickness of the glass substrate is used.

6. A vapor deposition method according to claim 5, wherein, as the cooling plate, a cooling plate having a thickness of 100 μm or larger and 1500 μm or smaller is used.

7. A vapor deposition method according to claim 1, wherein the cooling plate comprise a glass plate or a metal plate.

8. A vapor deposition method according to claim 1, wherein, as the glass substrate, a glass substrate having a thickness of 10 μm or larger and 700 μm or smaller and having a thermal conductivity of 0.1 W/m·k or larger and 1.5 W/m·k or smaller is used.

9. A vapor deposition system for forming by vapor deposition treatment, among one or a plurality of layers formed on a one surface side of a glass substrate, the one or the plurality of layers comprising an organic layer, at least one layer of the one or the plurality of layers, the vapor deposition system comprising a cooling plate for cooling the glass substrate in the vapor deposition treatment,
wherein one surface of the cooling plate is brought into direct surface contact with another surface of the glass substrate, and the contact surfaces of the cooling plate and the glass substrate are brought into an intimate contact with each other to an extent of being peelable by the direct surface contact.

10. A vapor deposition method according to claim 2, wherein, as the cooling plate, a cooling plate formed of a material having a thermal conductivity which is equivalent to or larger than a thermal conductivity of the glass substrate is used.

11. A vapor deposition method according to claim 2, wherein, as the cooling plate, a cooling plate having a thickness which is equivalent to or larger than a thickness of the glass substrate is used.

12. A vapor deposition method according to claim 3, wherein, as the cooling plate, a cooling plate having a thickness which is equivalent to or larger than a thickness of the glass substrate is used.

13. A vapor deposition method according to claim 4, wherein, as the cooling plate, a cooling plate having a thickness which is equivalent to or larger than a thickness of the glass substrate is used.

14. A vapor deposition method according to claim 10, wherein, as the cooling plate, a cooling plate having a thickness which is equivalent to or larger than a thickness of the glass substrate is used.

15. A vapor deposition method according to claim 2, wherein the cooling plate comprise a glass plate or a metal plate.

16. A vapor deposition method according to claim 3, wherein the cooling plate comprise a glass plate or a metal plate.

17. A vapor deposition method according to claim 4, wherein the cooling plate comprise a glass plate or a metal plate.

18. A vapor deposition method according to claim 5, wherein the cooling plate comprise a glass plate or a metal plate.

19. A vapor deposition method according to claim 6, wherein the cooling plate comprise a glass plate or a metal plate.

20. A vapor deposition method according to claim 10, wherein the cooling plate comprise a glass plate or a metal plate.
